(19) United States
(12) Patent Application Publication
(10) Pub. No.: US 2007/0088891 A1
(43) Pub. Date: Apr. 19, 2007

(54) Administrative computer module

(76) Inventors: John H. Kelly, Phoenix, AZ (US); Philippe R. Chevallier, Phoenix, AZ (US); Michael J. Werning, Cary, IL (US)

Correspondence Address: MOTOROLA, INC., LAW DEPARTMENT, 1303 E. ALGONQUIN ROAD, SCHAUMBURG, IL, 60196, US

(21) Appl. No.: 11/250,295

(22) Filed: Oct. 13, 2005

(51) Int. Cl. H05K 7/10

(52) U.S. Cl. 710/301

(57) ABSTRACT

An administrative computer module may include a first and second Compact Peripheral Component Interconnect (CompactPCI®) chassis, where each CompactPCI chassis includes a fabric slot coupled to accept a fabric board, where the fabric slot includes an interfabric link port, where the fabric board is coupled to operate a switched fabric on a first backplane. Each CompactPCI chassis may further include a plurality of node slots coupled to accept a plurality of node boards, where each of the plurality of node slots is coupled to the fabric slot via a first pair of node links. Each of the plurality of node boards in each CompactPCI chassis is operationally redundant. Further an interfabric link may couple the fabric slot of each chassis via the interfabric link port of each chassis.

### BACKGROUND OF INVENTION

Administrative computer modules are computer systems that provide configuration and control services to system operators utilizing racks of blade-based computer modules. Configuration and control services may include monitoring, alarming and notification functions. For example, administrative computer modules provide configuration and control services to blade-based computer modules in the telecommunications (telecom) industry. Each administrative computer module generally provides two units that operate in a cold standby configuration. Failure of one unit will cause a switch to the redundant unit so there is no single point of failure without recovery.

Prior art administrative computer modules are bussed architecture, proprietary systems that vary widely from one manufacturer to another. This makes it difficult for a system operator to mix and match equipment from different manufacturers and can unnecessarily tie a system operator to a single equipment manufacturer.

CompactPCI® packet switching backplane is an extension to the PCI Industrial Computer Manufacturers Group (PICMG®) 2.x family of specifications that overlays a packet-based switching fabric on top of CompactPCI® to create an Embedded System Area Network (ESAN). It supplements the hot-swap capable CompactPCI® architecture with the easily integrated, low-cost, high performance and extensible Ethernet.

There is a need, not met in the prior art, for a non-proprietary, fabric-based administrative computer module. Accordingly, there is a significant need for an apparatus that overcomes the deficiencies of the prior art outlined above.

### BRIEF DESCRIPTION OF THE DRAWINGS

Representative elements, operational features, applications and/or advantages of the present invention reside inter alia in the details of construction and operation as more fully hereafter depicted, described and claimed—reference being made to the accompanying drawings forming a part hereof, wherein like numerals refer to like parts throughout. Other elements, operational features, applications and/or advantages will become apparent in light of certain exemplary embodiments recited in the Detailed Description, wherein:

FIG. 1 representatively illustrates a block diagram of a prior art CompactPCI® computer module;

FIG. 2 representatively illustrates a computer system in accordance with an exemplary embodiment of the present invention;

FIG. 3 representatively illustrates a fabric board of a computer module in accordance with an exemplary embodiment of the present invention; and

FIG. 4 representatively illustrates a telecom computing rack in accordance with an exemplary embodiment of the present invention.

Elements in the Figures are illustrated for simplicity and clarity and have not necessarily been drawn to scale. For example, the dimensions of some of the elements in the Figures may be exaggerated relative to other elements to help improve understanding of various embodiments of the present invention. Furthermore, the terms “first”, “second”, and the like herein, if any, are used inter alia for distinguishing between similar elements and not necessarily for describing a sequential or chronological order. Moreover, the terms “front”, “back”, “top”, “bottom”, “over”, “under”, and the like in the Description and/or in the Claims, if any, are generally employed for descriptive purposes and not necessarily for comprehensively describing exclusive relative position. Any of the preceding terms so used may be interchanged under appropriate circumstances such that various embodiments of the invention described herein may be capable of operation in other configurations and/or orientations than those explicitly illustrated or otherwise described.

### DETAILED DESCRIPTION OF EXEMPLARY EMBODIMENTS

The following representative descriptions of the present invention generally relate to exemplary embodiments and the inventor's conception of the best mode, and are not intended to limit the applicability or configuration of the invention in any way. Rather, the following description is intended to provide convenient illustrations for implementing various embodiments of the invention. As will become apparent, changes may be made in the function and/or arrangement of any of the elements described in the disclosed exemplary embodiments without departing from the spirit and scope of the invention.

For clarity of explanation, the embodiments of the present invention are presented, in part, as comprising individual functional blocks. The functions represented by these blocks may be provided through the use of either shared or dedicated hardware, including, but not limited to, hardware capable of executing software. The present invention is not limited to implementation by any particular set of elements, and the description herein is merely representational of one embodiment.

Software blocks that perform embodiments of the present invention can be part of computer program modules comprising computer instructions, such control algorithms that are stored in a computer-readable medium such as memory. Computer instructions can instruct processors to perform any methods described below. In other embodiments, additional modules could be provided as needed.

A detailed description of an exemplary application, namely an administrative computer module, is provided as a specific enabling disclosure that may be generalized to any application of the disclosed system, device and method in accordance with various embodiments of the present invention.

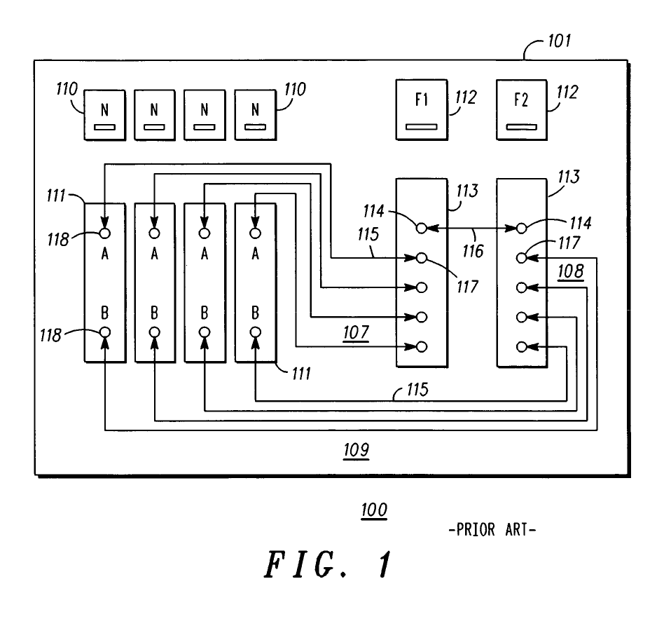

FIG. 1 representatively illustrates a block diagram of a prior art CompactPCI® computer module 100. In the prior art, CompactPCI® includes a single chassis 101, with software and any number of slots for inserting boards as defined in the CompactPCI® Packet Switching Backplane Specification 2.16 and other 2.x specifications published by PICMG, all of which are incorporated herein by reference. The chassis 101 includes one or two fabric slots 112, and up to nineteen node slots 110. Fabric slots 112 are each coupled to receive a fabric board 113 and each node slot 110 is coupled to receive a node board 111. Node links 115 couple the fabric slots 112 to the node slots 110. With one fabric board 113 installed, a star configuration is created, while the use of two fabric boards 113 creates a dual star configuration, both known in the art.

Each node link 115 coupling a fabric board 113 to a node board 111 represents a link that may be a 10/100/1000 Mbyte/second (Mbs) full-duplex Ethernet connection. Node boards 113 communicate by transferring/receiving packets to/from the fabric board 113, which transfers the packet to/from one or more node boards 111. Thus, every node board 111 can communicate with every other node board 111 and thereby form a fabric.

Each board is coupled to a backplane 109, which is a packet switched backplane. Node board 111 may, for example, add functionality to CompactPCI computer module 100 through the addition of processors, memory, storage devices, device interfaces, network interfaces, and the like.

Node boards 111 may be coupled to up to two switched fabrics. Each node slot 110 includes node board link ports 118, which are physical end ports (see IEEE 802.3-2000) of a slot-to-slot connection.

Fabric board 113 may operate as a central switching resource that may be coupled to any number of node boards 111. A fabric board 113 supports multiple link ports and provides switching and/or routing functions to create a fabric between node boards 111. Fabric slots 112 include fabric board link ports 117, which are physical end ports of a slot-to-slot connection. In the prior art, node slot 110 may have two node board link ports 118 each coupled to a different fabric slot 112 and hence to a separate switched fabric (first switched fabric 107 and second switched fabric 108).

Fabric slot 112 may also include at least one interfabric link port 114, which is a physical end port of a slot-to-slot connection and is used to couple fabric boards 113 via at least one interfabric link 116. Interfabric link port 114 may also be known in as link port “f” under CompactPCI, which indicates that the interfabric link port is used for a fabric-to-fabric connection. As shown, interfabric link 116 provides a fabric to fabric connection linking first switched fabric 107 with second switched fabric 108. Interfabric link port 114 is coupled to interface with the rear portion of a fabric board 113 and is coupled to interfabric link 116 on the backplane. This is contrasted with external fabric ports on the front of fabric board 113 (not shown for clarity), which allow fabric board to be coupled to external devices.

In the prior art, CompactPCI included one chassis 101 that supported up to two switched fabrics (first switched fabric 107 and second switched fabric 108) though each of two fabric boards 113 as shown in FIG. 1. Generally, each switched fabric was operationally redundant, meaning that one switched fabric may perform the same function as the other switched fabric. Therefore, one of first switched fabric 107 and second switched fabric may operate as a cold standby or a hot standby. To provide this redundancy and the accompanying reliability, each node board 111 is independently coupled to each of the first switched fabric 107 and second switched fabric 108 via node board link ports 118 and node links 115 as shown. So if one fabric board and hence one switched fabric were to fail, the node board may still operate on the other switched fabric using the other fabric board. For example, if first switched fabric failed, node boards 111 may still operate using second switched fabric 108. Switched fabrics may update each other in a hot standby configuration using interfabric link port 114 and interfabric link 116. In sum, the prior art provides a single CompactPCI chassis supporting two operationally redundant switched fabrics with each node board coupled non-redundantly to each switched fabric.

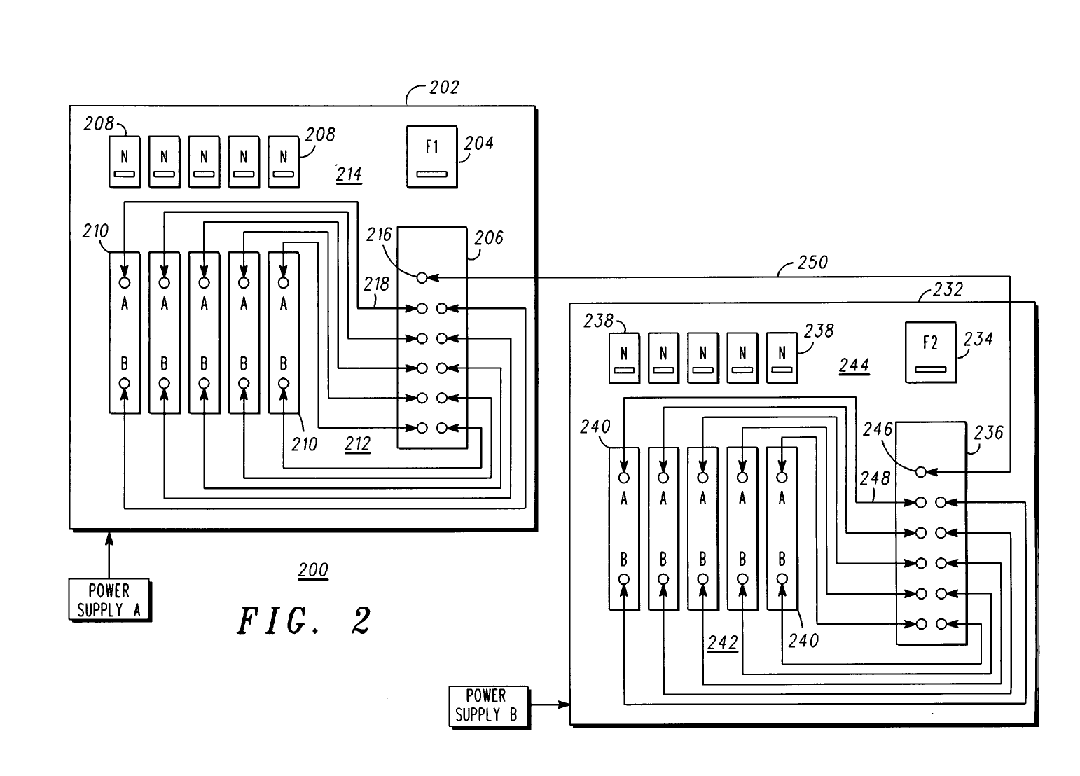

FIG. 2 representatively illustrates a computer system 200 in accordance with an exemplary embodiment of the present invention. Computer system 200 includes first CompactPCI chassis 202 and second CompactPCI chassis 232, each electrically independent of each other and having their own independent power supplies (power supply A and power supply B respectively).

In an embodiment, each of first CompactPCI chassis 202 and second CompactPCI chassis 232 can have a 3U form factor. As is known in the art, “U” and multiples of “U” can refer to the height of a module or width of an expansion card. In an embodiment, “U” can measure approximately 1.75 inches. Although boards in each of first CompactPCI chassis 202 and second CompactPCI chassis 232 are shown as vertical, this is not limiting of the invention. Horizontally disposed boards with the chassis are within the scope of the invention.

Each of first CompactPCI chassis 202 and second CompactPCI chassis 232 are designed to accept boards complying with the CompactPCI specifications, particularly PICMG® 2.x family of specifications that overlays a packet-based switching fabric on top of CompactPCI® to create an Embedded System Area Network (ESAN). That is to say, that first CompactPCI chassis 202 and second CompactPCI chassis 232 are coupled to receive and operate using boards having form factors and electrical requirements complying with CompactPCI.

In an embodiment, first CompactPCI chassis 202 may include a first fabric slot 204 coupled to accept a first fabric board 206, where the first fabric slot 204 includes a first interfabric link port 216. First fabric board 206 is coupled to operate as a switch/router for a first switched fabric 214 on first backplane 212. First switched fabric 214 may operate using 10 Mbps, 100 Mbps or 1 Gigabyte/second (Gbps) Ethernet. In an embodiment, first fabric slot 204 may include one or more interfabric link ports 216.

First CompactPCI chassis 202 may also include first plurality of node slots 208 coupled to accept first plurality of node boards 210. In an embodiment, each of first plurality of node slots 208 is coupled to first fabric slot 204 via a first pair of node links 218. First pair of node links 218 may interface with first fabric slot 204 via fabric board link ports as shown in FIG. 2. In an embodiment, first plurality of node slots 208 may include five first node slots where first CompactPCI chassis 202 is a six slot, 3U chassis.

In an embodiment, second CompactPCI chassis 232 may include a second fabric slot 234 coupled to accept a second fabric board 236, where the second fabric slot 234 includes a second interfabric link port 246. Second fabric board 236 is coupled to operate as a switch/router for a second switched fabric 244 on second backplane 242. Second switched fabric 244 may operate using 10 Mbps, 100 Mbps or 1 Gigabyte/second (Gbps) Ethernet. In an embodiment, second fabric slot 234 may include one or more interfabric link ports 246.

Second CompactPCI chassis 232 may also include second plurality of node slots 238 coupled to accept second plurality of node boards 240. In an embodiment, each of second plurality of node slots 238 is coupled to second fabric slot 234 via a second pair of node links 248. Second pair of node links 248 may interface with second fabric slot 234 via fabric board link ports as shown in FIG. 2. In an embodiment, second plurality of node slots 238 may include five first node slots where second CompactPCI chassis 232 is a six slot, 3U chassis.

In an embodiment, second plurality of node boards 240 is operationally redundant with first plurality of node boards 210. Operationally redundant may mean that the functionality of the first plurality of node boards 210 is the same as the functionality of the second plurality of node boards 240. For example, the storage, memory or processing capability present in the first plurality of node boards 210 is also present in the second plurality of node boards 240. As another example, the tasks performed by the first plurality of node boards 210 may also be performed by the second plurality of node boards 240.

In an embodiment, interfabric link 250 couples first fabric slot 204 to second fabric slot 234 via first interfabric link port 216 and second interfabric link port 246. In an embodiment, first interfabric link port and second interfabric link port 246 may be link ports “f” designed for a fabric-to-fabric interface linking first switched fabric 214 and second switched fabric 244.

As shown in FIG. 2, first CompactPCI chassis 202 includes only a single fabric slot, first fabric slot 204, and operates only one switched fabric, first switched fabric 214. Further, first plurality of node boards 210 are redundantly coupled to first fabric slot 204 though a first pair of node links 218.

Also, second CompactPCI chassis 232 includes only a single fabric slot, second fabric slot 234, and operates only one switched fabric, second switched fabric 244. Further, second plurality of node boards 240 are redundantly coupled to second fabric slot 234 though a second pair of node links 248.

This configuration differs from the prior art in that each switched fabric is contained in a separate, electrically isolated CompactPCI chassis and each node board is redundant to a single switched fabric instead of being coupled to both switched fabrics, while both the first switched fabric 214 and second switched fabric 244 remain coupled over the interfabric link 250. The interfabric link 250 may be a single link or a redundant dual link. Further, the interfabric link port may be used to couple the first fabric slot 204 to the second fabric slot 234 as will be shown below in reference to FIG.3. This configuration offers redundancy and reliability in a compact 3U chassis. For example, each of first plurality of node boards 210 has a redundant counterpart in second plurality of node boards 240. So, if one of first plurality of node boards fails, its counterpart in second plurality of node boards automatically takes over. Also, if one of first pair of node links 218 linking one of first plurality of node boards 210 to first fabric board 206, communication remains uninterrupted due to the redundant pair of node links linking the node board to the first fabric board 206. In addition, if power to one of the CompactPCI chassis fails, the system does not fail as the other CompactPCI chassis remains in operation with its own switched fabric.

FIG. 3 representatively illustrates a fabric board 306 of a computer module 300 in accordance with an exemplary embodiment of the present invention. Computer module 300 includes fabric board 306, backplane 312 CompactPCI chassis and rear transition module 349. CompactPCI chassis 302 includes a front portion 362 and a rear portion 360. As shown, fabric slot containing fabric board 306 includes an interfabric link port 316. In an embodiment, there can be two interfabric link ports 316. In the prior art, interfabric link port 316 is used to couple one fabric board and switched fabric to another fabric board and another switched fabric as shown in FIG. 1. In the prior art, both switched fabrics were in the same chassis. However, in an embodiment, of the invention, the same interfabric link port 316 may be used to couple a switched fabric board and switched fabric in one chassis, to another switched fabric board and another switched fabric in another chassis as shown in FIG. 2. In this way, no reconfiguration of a fabric board used in the prior art is required to use the same fabric board in the embodiment of the invention depicted in FIG. 2.

Fabric board 306 may also include front external fabric ports 317, which may be used to couple a switched fabric to a device or network outside of the chassis. However, to use front external fabric ports 317 in the embodiment depicted in FIG. 2 requires modification of the fabric board as the front external fabric ports are not designed under CompactPCI to link two redundant switched fabrics.

The use of interfabric link port 316, whether one or two ports are present, offers the advantage of not having to modify the fabric board and the further advantage of allowing the pair of interfabric link 350 to exit the CompactPCI chassis 302 though the rear portion 360 as opposed to the front portion if the front fabric ports were used. This allows the linking of the first switched fabric in the first CompactPCI chassis to the second switched fabric in the second CompactPCI chassis without cluttering up frontal access to the chassis which is often used for routine monitoring and maintenance of the CompactPCI chassis. In an embodiment, interfabric link 350 may exit though a rear transition module 349 or from the backplane itself using a dedicated connector.

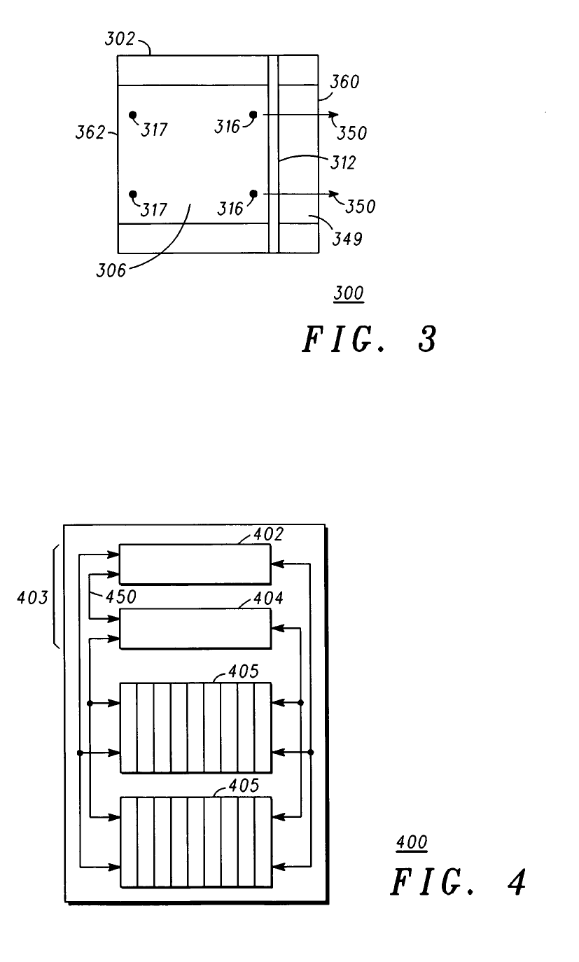

FIG. 4 representatively illustrates a telecom computing rack 400 in accordance with an exemplary embodiment of the present invention. A telecom computing rack may include any number of telecom computing modules 405 coupled detect and switch telecom traffic such as voice data, packet data, and the like. An example of telecom computing modules may be Advanced Telecom Computer Architecture (ATCA) computing modules as defined in PICMG 3.x series of specifications. These can include a slot/blade design coupled together with a backplane. The use of ATCA telecom modules is not limited to ATCA, and telecom modules operating other than ATCA are within the scope of the invention.

Telecom computing rack 400 may also include administrative computer module 403 coupled to monitor set of telecom computing modules 405. Administrative computer module 403 may provide configuration and control services to telecom computing rack 400, which may include monitoring, alarming and notification functions. For example, administrative computer module may monitor set of telecom modules for blade failure, cooling temperature and failure, missing blades, traffic volume, and the like. Administrative computer module 403 may also provide alarming and notification functions to a system operator. In an embodiment, administrative computer module 403 may include first CompactPCI chassis 402 and second CompactPCI chassis 404 through interfabric link 450 as described with reference to FIG. 2. Administrative computer module using this embodiment allows the use of standardized CompactPCI fabric boards and node boards while maintaining redundancy and reliability required in the rigorous telecom computing environment. The use of standardized CompactPCI boards in the administrative computer module 403 allows system operators to operate a familiar and ubiquitous fabric network that is familiar and well-established as opposed to prior art proprietary administrative solutions.

In the foregoing specification, the invention has been described with reference to specific exemplary embodiments; however, it will be appreciated that various modifications and changes may be made without departing from the scope of the present invention as set forth in the claims below. The specification and figures are to be regarded in an illustrative manner, rather than a restrictive one and all such modifications are intended to be included within the scope of the present invention. Accordingly, the scope of the invention should be determined by the claims appended hereto and their legal equivalents rather than by merely the examples described above.

For example, the steps recited in any method or process claims may be executed in any order and are not limited to the specific order presented in the claims. Additionally, the components and/or elements recited in any apparatus claims may be assembled or otherwise operationally configured in a variety of permutations to produce substantially the same result as the present invention and are accordingly not limited to the specific configuration recited in the claims.

Benefits, other advantages and solutions to problems have been described above with regard to particular embodiments; however, any benefit, advantage, solution to problem or any element that may cause any particular benefit, advantage or solution to occur or to become more pronounced are not to be construed as critical, required or essential features or components of any or all the claims.

As used herein, the terms “comprise”, “comprises”, “comprising”, “having”, “including”, “includes” or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present invention, in addition to those not specifically recited, may be varied or otherwise particularly adapted to specific environments, manufacturing specifications, design parameters or other operating requirements without departing from the general principles of the same.

We claim:

1. A computer system, comprising:
a first Compact Peripheral Component Interconnect (CompactPCI) chassis, comprising:
a first fabric slot coupled to accept a first fabric board, wherein the first fabric slot includes a first interfabric link port, wherein the first fabric board is coupled to operate a first switched fabric on a first backplane;
a first plurality of node slots coupled to accept a first plurality of node boards, wherein each of the first plurality of node slots is coupled to the first fabric slot via a first pair of node links;
a second CompactPCI chassis, comprising:
a second fabric slot coupled to accept a second fabric board, wherein the second fabric slot includes a second interfabric link port, wherein the second fabric board is coupled to operate a second switched fabric on a second backplane;
a second plurality of node slots, coupled to accept a second plurality of node boards, wherein each of the second plurality of node boards is coupled to the second fabric slot via a second pair of node links, wherein the second plurality of node boards are operationally redundant to the first plurality of node boards; and
an interfabric link coupling the first fabric slot to the second fabric slot via the first interfabric link port and the second interfabric link port.

2. The computer system of claim 1, wherein the first switched fabric and the second switched fabric are operationally redundant.

3. The computer system of claim 1, wherein the first switched fabric and the second switched fabric operate using at least one of 10 Mbps Ethernet, 100 Mbps Ethernet and 1 Gbps Ethernet.

4. The computer system of claim 1, wherein the first plurality of node slots includes five first node slots, and wherein the second plurality of node slots includes five second node slots.

5. The computer system of claim 1, wherein each of the first CompactPCI chassis and the second CompactPCI chassis has a 3U form factor.

6. The computer system of claim 1, wherein the first interfabric link port and the second interfabric link port are link ports “f” coupled to link the first switched fabric to the second switched fabric.

7. The computer system of claim 1, wherein the interfabric link is coupled to interface a rear portion of the first CompactPCI chassis and the second CompactPCI chassis.

8. An administrative computer module coupled to monitor a set of telecom computing modules, comprising:
a first Compact Peripheral Component Interconnect (CompactPCI) chassis, comprising:
a first fabric slot coupled to accept a first fabric board, wherein the first fabric slot includes a first interfabric link port, wherein the first fabric board is coupled to operate a first switched fabric on a first backplane;
a first plurality of node slots coupled to accept a first plurality of node boards, wherein each of the first plurality of node slots is coupled to the first fabric slot via a first pair of node links;
a second CompactPCI chassis, comprising:
a second fabric slot coupled to accept a second fabric board, wherein the second fabric slot includes a second interfabric link port, wherein the second fabric board is coupled to operate a second switched fabric on a second backplane;
a second plurality of node slots, coupled to accept a second plurality of node boards, wherein each of the second plurality of node boards is coupled to the second fabric slot via a second pair of node links, wherein the second plurality of node boards are operationally redundant to the first plurality of node boards, and wherein the first plurality of node boards and the second plurality of node boards are coupled to the set of telecom computing modules; and
an interfabric link coupling the first fabric slot to the second fabric slot via the first interfabric link port and the second interfabric link port.

9. The administrative computer module of claim 8, wherein the first switched fabric and the second switched fabric are operationally redundant.

10. The administrative computer module of claim 8, wherein the first switched fabric and the second switched fabric operate using at least one of 10 Mbps Ethernet, 100 Mbps Ethernet and 1 Gbps Ethernet.

11. The administrative computer module of claim 8, wherein the first plurality of node slots includes five first node slots, and wherein the second plurality of node slots includes five second node slots.

12. The administrative computer module of claim 8, wherein each of the first CompactPCI chassis and the second CompactPCI chassis has a 3U form factor.

13. The administrative computer module of claim 8, wherein the first interfabric link port and the second interfabric link port are link ports “f” coupled to link the first switched fabric to the second switched fabric.

14. The administrative computer module of claim 8, wherein the interfabric link is coupled to interface a rear portion of the first CompactPCI chassis and the second CompactPCI chassis.

15. A telecom computing rack having an administrative computer module, the administrative computer module comprising:
a first Compact Peripheral Component Interconnect (CompactPCI) chassis, comprising:
a first fabric slot coupled to accept a first fabric board, wherein the first fabric slot includes a first interfabric link port, wherein the first fabric board is coupled to operate a first switched fabric on a first backplane;
a first plurality of node slots coupled to accept a first plurality of node boards, wherein each of the first plurality of node slots is coupled to the first fabric slot via a first pair of node links;
a second CompactPCI chassis, comprising:
a second fabric slot coupled to accept a second fabric board, wherein the second fabric slot includes a second interfabric link port, wherein the second fabric board is coupled to operate a second switched fabric on a second backplane;
a second plurality of node slots, coupled to accept a second plurality of node boards, wherein each of the second plurality of node boards is coupled to the second fabric slot via a second pair of node links, wherein the second plurality of node boards are operationally redundant to the first plurality of node boards; and
an interfabric link coupling the first fabric slot to the second fabric slot via the first interfabric link port and the second interfabric link port.

16. The telecom computing rack of claim 15, wherein the first switched fabric and the second switched fabric are operationally redundant.

17. The telecom computing rack of claim 15, wherein the first switched fabric and the second switched fabric operate using at least one of 10 Mbps Ethernet, 100 Mbps Ethernet and 1 Gbps Ethernet.

18. The telecom computing rack of claim 15, wherein the first plurality of node slots includes five first node slots, and wherein the second plurality of node slots includes five second node slots.

19. The telecom computing rack of claim 15, wherein each of the first CompactPCI chassis and the second CompactPCI chassis has a 3U form factor.

20. The telecom computing rack of claim 15, wherein the first interfabric link port and the second interfabric link port are link ports “f” coupled to link the first switched fabric to the second switched fabric.

21. The telecom computing rack of claim 15, wherein the interfabric link is coupled to interface a rear portion of the first CompactPCI chassis and the second CompactPCI chassis.
